(19) United States
(12) Patent Application Publication
(10) Pub. No.: US 2007/0288813 A1
(43) Pub. Date: Dec. 13, 2007

(54) Cell board interconnection architecture with serviceable switch board

(76) Inventors: Christian L. Belady, Richardson, TX (US); Eric C. Peterson, Richardson, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/414,852

(22) Filed: May 1, 2006

(51) Int. Cl. G01R 31/28

(52) U.S. Cl. 714/724

(57) ABSTRACT

In certain embodiments, there is provided a computer system and a method for providing a computer system. Specifically, there is provided a computer system that may include a porous main board that is configured to couple to a plurality of switch boards. The porous main board may be configured to conduct air flowing from the front to the back of the computer system and to permit the switch boards to be serviced from the front or back of the computer system. Moreover, in certain embodiments, the switch boards may be hot-swappable.

### BACKGROUND

This section is intended to introduce the reader to various aspects of art, which may be related to various aspects of the present invention that are described or claimed below. This discussion is believed to be helpful in providing the reader with background information to facilitate a better understanding of the various aspects of the present invention. Accordingly, it should be understood that these statements are to be read in this light, and not as admissions of prior art.

Multi-processor computer systems are often constructed from cell boards. A cell board typically includes a processor, memory, application specific integrated circuits (ASICs), power converters, and input and/or output connectors. In certain computer systems, the cell boards are coupled to a backplane. The computer system may also include a switch board to facilitate the transmission of signals between cell boards. The switch board may connect to multiple cell boards or to the backplane and route signals to and from the cell boards.

Unfortunately, the dense arrangement of the backplane, cell boards, and switch boards results in poor cooling and serviceability. For example, the backplane typically blocks airflow in a front to back direction, or vice versa. In some computer systems, the switch boards and many of the cell boards are mounted in a non-serviceable location. For example, the switch boards may be blocked by other components, cell boards, or the chassis of the computer, such that the switch boards cannot be serviced without shutting down and partially disassembling the computer system.

### BRIEF DESCRIPTION OF THE DRAWINGS

FIG. 1 is a front perspective view illustrating an exemplary computer system with front-to-back airflow, a porous main board, and switch boards that are hot-swappable and serviceable from the front or rear of the system in accordance with embodiments of the present technique;

FIG. 2 is a front perspective view illustrating an exemplary computer system with four cell board arrays coupled to a porous main board;

FIG. 3 is a front perspective view illustrating a horizontal mid-plane board that may be included in the embodiment of FIG. 2;

FIG. 4A is a front perspective view illustrating the front face of a center vertical mid-plane that may be included in the embodiment of FIG. 2;

FIG. 4B is a front perspective view illustrating the rear face of a center vertical mid-plane that may be included in the embodiment of FIG. 2;

FIG. 5A is a front perspective view illustrating the front face of a right vertical mid-plane that may be included in the embodiment of FIG. 2;

FIG. 5B is a front perspective view illustrating the rear face of a right vertical mid-plane that may be included in the embodiment of FIG. 2;

FIG. 6A is a front perspective view illustrating the front face of a left vertical mid-plane that may be included in the embodiment of FIG. 2;

FIG. 6B is a front perspective view illustrating the rear face of a left vertical mid-plane that may be included in the embodiment of FIG. 2;

FIG. 7 is a front perspective view illustrating an exemplary porous main board that may be constructed from the components depicted in FIGS. 3-6;

FIG. 8 is a front perspective view illustrating an exemplary switch board that may be included in the embodiment of FIG. 2;

FIG. 9 is a front perspective view illustrating a second embodiment of an exemplary switch board that may be included in the embodiment of FIG. 2;

FIG. 10 is a front perspective view illustrating an exemplary computer system employing a split porous main board and two cell board arrays;

FIG. 11 is a perspective view illustrating an exemplary split porous main board that may be included in the embodiment of FIG. 10; and

FIG. 12 is a front perspective view illustrating an exemplary computer system including a cabinet.

### DETAILED DESCRIPTION OF SPECIFIC EMBODIMENTS

One or more exemplary embodiments of the present invention will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Multi-processor computer systems are often constructed from cell boards. A cell board typically includes a processor, memory, application specific integrated circuits (ASICs), power converters, and input and output connectors. A multi-processor computer system may include multiple cell boards. Typically, the cell boards connect to one another so they can coordinate their operations. Advantageously, by dividing some computing tasks among a plurality of cell boards, a multi-processor computer system may perform many computing tasks faster than a single processor system.

The cell boards may be connected with cables and/or a backplane to form a computer system. Cables between each of the cell boards facilitate cell board to cell board communication and the division of computer tasks. However a large number of cables may be time consuming and complex to connect and route. A backplane may simplify assembly of the computer. Typically, a backplane includes connectors to receive the input and output connectors on the cell boards. The backplane may include an array of connectors to receive a large number of cell boards. Often, computer systems employ an array of cell boards connected to one another through a backplane. Typically, a backplane includes several layers of routing through which signals to and from the cell boards may pass. Through this routing, the cell boards may communicate with one another, dividing up computing tasks and sharing memory.

To facilitate the transmission of signals between cell boards, a computer system may also include a switch board. The switch board may connect to multiple cell boards or to the backplane and route signals to and from the cell boards. Often, a switch board cooperates with a backplane to transmit signals between the cell boards. Switch boards may be passive or active. A passive switch board may employ routing layers to direct signals between the various portions of the system. In contrast, an active switch board may include logic circuitry to actively arbitrate the path of signals between the various portions of the system. Active switch boards typically include routing layers; however, active switch boards may offer routing layers with a shorter path between components. Often, several cell boards communicate with one another through the routing layers. With passive routing, the number of routing paths to connect each additional cell board may increase as a factorial of the number of cell boards being directly connected. Thus, directly connecting a large number of cell boards with passive routing may lead to complex routing paths and higher signal latency. In contrast, active routing may employ a hub and spoke system of communication, with each cell board connected to the logic circuitry. Thus, each additional cell board typically requires one additional routing path to the logic circuitry on the switch board, rather than a path to every other cell board. Typically, the logic circuitry arbitrates the path of the signal between the various portions of the system, reducing the complexity of the routing layers. Moreover, the logic circuitry may actively allocate bandwidth, thereby opening additional lines of communication between cell boards as needed. Some systems may employ a hybrid approach, with a baseline level of passive bandwidth and additional actively allocated links of communication.

When a backplane and a switch board are coupled to multiple cell boards, the resulting structure is often referred to as a cabinet. A single cabinet may be employed as a server, or a series of cabinets may be connected to form a server with greater computing power. The cabinet may also include a bulk power supply, input and output connectors, and fans to circulate air to through the cabinet. Additionally, the cabinet may include a shell to house and support these various components.

Often, multi-processor computer systems constructed from cell boards are modular and scalable. Typically, when a backplane includes unused slots, more cell boards can be added to increase the systems computing power. Often, multiple backplanes may be connected to one another to add the capacity to support additional cell boards. Similarly, multiple cabinets may be connected to one another to add even more computing power.

Designers of multi-processor computer systems face several design considerations. For example, cooling a multi-processor computer system may present challenges. Often, the cell boards include several components that generate heat, such as processors, memory, ASICs, and power converters. To dissipate this heat, the cell boards may include heat sinks that are attached to some of these components. However, when many cell boards are placed in proximity, such as in a cabinet, the heat sinks may not be able to dissipate the heat generated by the cell boards. The air surrounding the heat sinks may become too warm to carry additional heat away from the cell boards. Fans blowing air across the heat sinks may enhance the capacity of the heat sinks to dissipate heat. However, the effectiveness blowing air across the heat sinks may turn on the volume and temperature of air flowing through the system. Often, air that has already been heated by one cell board may do little to cool a cell board further upstream. Similarly, air that has already been heated in one cabinet may do little to cool another cabinet that is upstream. Thus, placing the air intake of one cabinet near the exhaust of a second cabinet may leave the first cabinet with diminished cooling capacity, as pre-heated air may do little to cool the cell boards. As a consequence, designers are often limited in how close they may place cabinets to one another.

Other factors may limit the capacity of a cabinet to dissipate heat. For instance, the arrangement of components within a cabinet may limit the volume of air passing over a cell board. The more air that passes over a heat sink on a cell board, the greater that heat sinks capacity to dissipate heat into the air. However, many backplanes block the flow of air through a system. Often, a backplane is a solid two dimensional structure that extends along an entire array of cell boards. Solid two dimensional backplanes may limit the flow of air across the cell boards unless the airflows parallel to the backplane. However, directing airflow parallel to the backplane may leave the designer to make tradeoffs with other design considerations, such as system density and serviceability.

Designers may desire to increase the density of multi-processor system. Density refers to the amount of computing power available in a given unit of space. Customers often prefer a system with more computing power in less space to conserve server room space. Often, the rooms housing servers include expensive temperature control, fire suppression, and conduit systems, making server room floor space very valuable. Customers may prefer increasing the computing power within an existing space to constructing additional space to house more computer systems. Secondly, placing cell boards closer to one another may permit them to operate faster. Shorter signal paths may decrease latency, allowing cell boards to communicate with higher bandwidths and divide computing tasks more efficiently. Similarly, placing cabinets next to one another may decrease the time a signal takes to pass between cabinets, allowing the cabinets to operate faster as a system. To this end, designers often place an array of cabinets side by side, in a row.

Finally, designers may consider the serviceability of a system when designing a multi-processor computer system. Often multi-processor computer systems perform tasks that are critical for a customer's business. Consequently, customers often prefer that the computer system continue to function when a component within the system fails, is upgraded, or is replaced. Components that may be replaced while the system operates are said to be “hot-swappable.” Advantageously, a failure or replacement of a hot-swappable component may not cause the entire computer system to fail, leading to increased system uptime and facilitating maintenance operations.

Additionally, consumers of multi-processor computer systems typically desire a component to be serviceable from the front or back of a cabinet. Several cabinets are often placed side by side in a row, preventing access from the side. To remove a component that is not accessible from the front or back, a user may have to move the entire cabinet from the row to access the component from the side. This may interrupt the operation of other portions of the system and add to the costs of maintaining the system. Thus, making components accessible from the front or back of a system may increase system serviceability.

Often designers make tradeoffs between these three design considerations: heat dissipation, density, and serviceability. For example, computer systems employing traditional solid two dimensional backplanes may leave designers to choose between heat dissipation and serviceability. The solid backplane may obstruct the flow of air over the cell boards. To avoid this, a designer may direct the airflow parallel to the backplane, i.e. side to side airflow. However, in a row of cabinets, the exhaust of one cabinet may be directed toward the air intake of the next cabinet, resulting in reduced heat dissipation. On the other hand, if the backplane is placed on the side of a cabinet, to permit front-to-back airflow, the serviceability of the cabinet may be impaired. Often, cell boards and switch boards decouple from a backplane by moving in a direction that is orthogonal to a face of the backplane. Thus, with a side-mounted backplane, the adjacent cabinet may block the removal of a cell board or switch board. Consequently, solid two dimensional backplanes may lead to tradeoffs between heat dissipation and serviceability. In another example, a design may employ bottom-to-top airflow. However, with this type of airflow, rack space may be sacrificed to turn the air upward or downward.

The following discussion describes certain embodiments of the present invention that improve cooling and serviceability during operation of the computer system. As will be discussed in greater detail below, some of these embodiments include a porous main board coupled to redundant switch boards that are accessible from the front or the back of the system. Advantageously, these porous main boards enable air flow through the computer system, whereas solid two dimensional backplanes prevent airflow. For instance, in addition to the routing circuitry layers and connectors found on a solid two dimensional backplane, some porous main boards include apertures through which air may flow. In certain embodiments, the apertures are oriented to permit front-to-back airflow, such that the porous main boards may be placed facing the front of a cabinet without blocking front-to-back airflow, unlike solid two dimensional backplanes. Additionally, some embodiments discussed below enable the cell boards to connect to the porous main board from the front and back, thereby permitting the cell boards to be serviced from the front or back of the system. Thus, certain embodiments of a porous main board may permit cabinets to be placed side by side with front-to-back airflow and front and back serviceability of the cell boards and switch boards. Moreover, certain embodiments may include pairs of switch boards that are hot-swappable, e.g. one switch board may continue to function when the other switch board is removed. Thus, certain embodiments of the present techniques may improve the serviceability of computer systems and increase up-time, so the system 10 can keep running.

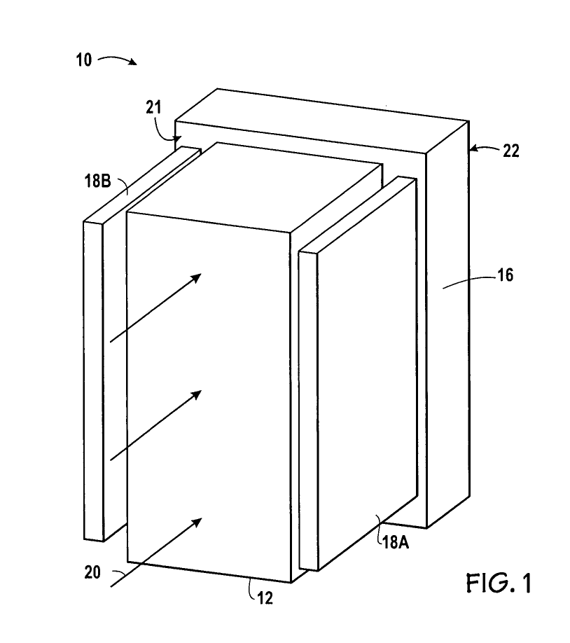

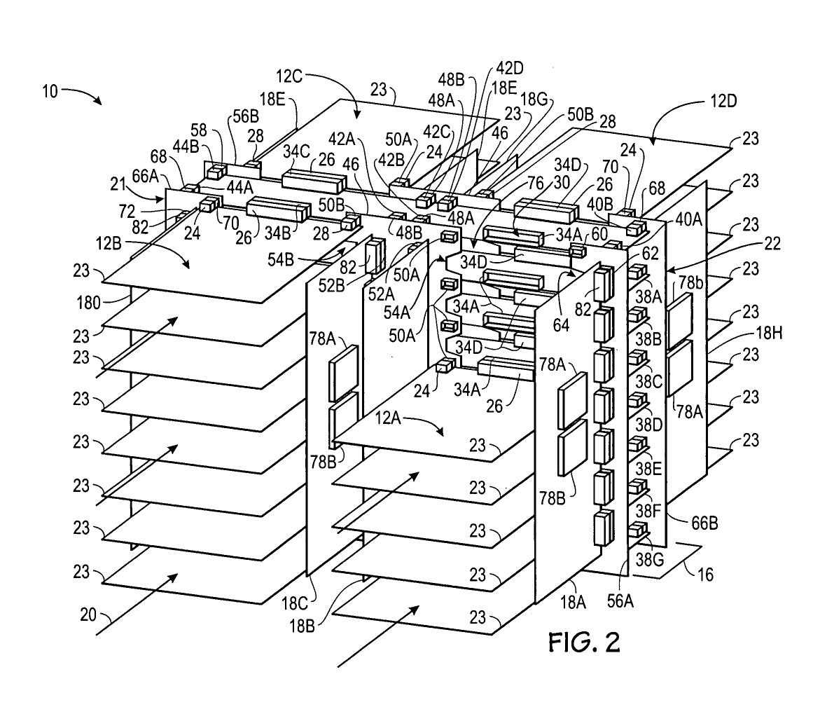

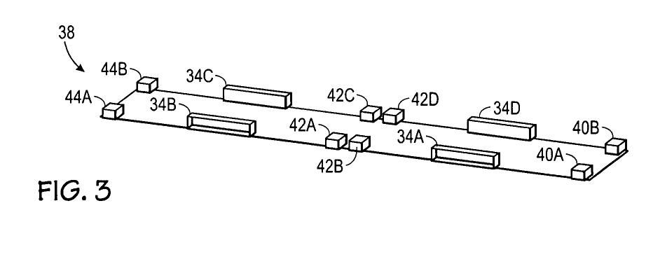

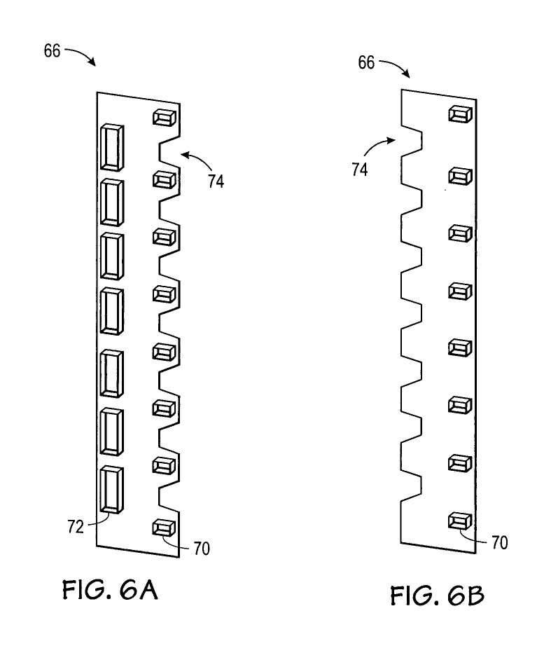

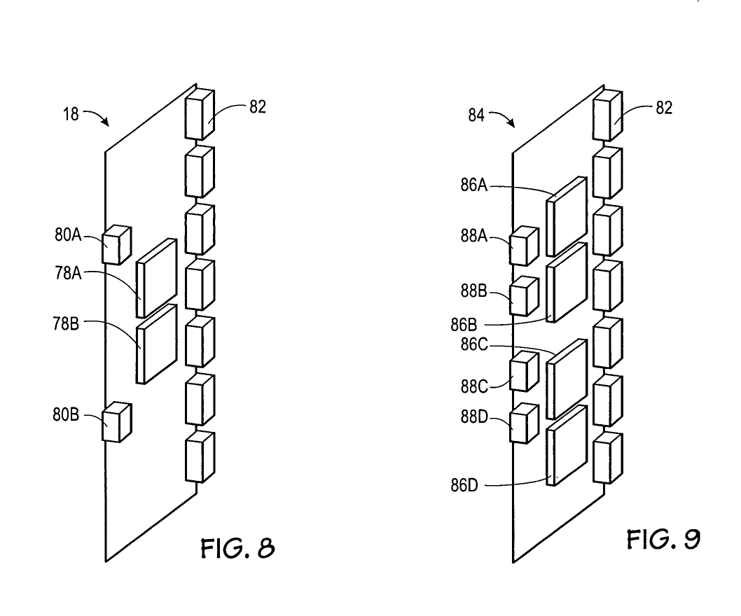

The following discussion provides several examples of embodiments of computer systems in accordance with the present technique. For example, FIG. 1 depicts a simplified view of a computer system, FIG. 2 depicts a more detailed view of an exemplary embodiment, and FIGS. 3-8 depict components that may be included within the embodiment of FIG. 2. Finally, FIGS. 9-12 illustrate other exemplary embodiments. It should be noted that these embodiments are merely exemplary and are not intended to limit the scope of the present techniques.

The following depictions of various exemplary embodiments are labeled with reference numbers. Where multiple components may be similar, one exemplary component may be labeled with a reference number, and the group of components may be referred to with the reference number marking the exemplary component. This convention is adopted for simplicity and does not to imply that components with the same reference number must be similar or that components with different reference numbers may not be similar.

To facilitate the introduction of the various components that may be included in an exemplary embodiment, FIG. 1 depicts a simplified perspective view of a computer system 10 in accordance with the present technique. The computer system 10 may be employed as a server, such as an application server, audio/video server, chat server, fax server, file transfer protocol server, groupware server, internet relay chat server, list server, mail server, news server, telnet server, or web server, for example. Alternatively, the computer system may be employed as a mainframe, workstation, or other single or multi-processor system.

The illustrated computer system 10 includes a cell board array 12 to perform computing tasks. The cell board array 12 includes one or more cell boards, examples of which are described in greater detail below. The cell board array 12 has a plurality of parallel cell boards in spaced relation. The cell boards in the array 12 may be horizontal, vertical, both horizontal and vertical, or partially or entirely in some other orientation. Spaces between the cell boards ensure that air may flow between the cell boards, thereby improving the convective heat transfer and cooling of the cell board array 12. The cell boards may be arranged by stacking them vertically, horizontally, or in some other arrangement that efficiently uses space. While the cell board array 12 is depicted as a solid block to simplify its introduction, it may include spaces through which air may flow, such as between the cell boards. Many of the computing tasks performed by the computer system 10 may be performed within the cell board array, such as storage of data in memory, recall of data in memory, and logical functions, for example.

In certain embodiments, a cell board includes a circuit board with a processor, memory, an application specific integrated circuit (ASIC), power converters, input and output connectors, or some combination of these components for performing computing tasks. In some embodiments, the cell board includes a plurality of processors, such as 2, 3, 4, 5, 6, 7, 8, 16, or 32, for example. The ASIC, or, in some embodiments, a plurality of ASICS, may route signals between the various components on the cell board and/or between the various components on the cell board and other cell boards. In other words, in some embodiments, the ASIC is a routing chip. Some exemplary cell boards include memory in the form of one or more dual inline memory modules (DIMMs), which may include dynamic random access memory (DRAM) or other forms of memory. Additionally, a cell board may include heat sinks attached to various components, such as the processor, ASIC, DIMMs, and/or power converters, for example.

Various other components within the computer system 10 may facilitate communication between the cell boards within the cell board array 12. For example, a porous main board 16 may communicatively couple to the cell board array 12. The porous main board 16 may include routing circuitry layers through which the various components of the cell board array 12 may communicate. The routing circuitry layers may carry signals both horizontally and vertically. Additionally, the porous main board 16 may communicatively couple to other systems. The porous main board 16 may be passive or active. An active porous main board may perform certain logic functions, such as actively routing circuitry signals between the cell boards. A passive main board 16 may facilitate a high system up-time. Passive main boards 16 often include few components subject to failure. Thus, a passive main board 16 may not require service very often.

The porous main board 16 includes apertures, channels, or other passages through which air may flow to cool components within the computer system 10. The apertures, channels, or other passages may be configured to allow a substantial portion of the front-to-back airflow. To enhance the flow of air through the porous main board 16, it may include baffles to lower drag, such as baffles forming cones or nozzles arranged around the apertures, channels, or other passages. The porous main board 16 may be a porous mid-plane, porous backplane, or other routing circuitry structure through which air may flow.

The porous main board 16 exemplifies a porous circuit board. A porous circuit board includes sufficient open area to conduct a substantial portion of the airflow through a computer system 10. In some embodiments, the porous circuit board allows more than 30%, 40%, 50%, 60%, 70%, 80%, 90%, 95%, or 100% of the air flowing through the computer system 10. Additionally, in certain embodiments, a porous circuit board includes more than 10%, 30%, 50%, 70%, 90%, or 95% cumulative open area to conduct a substantial portion of the airflow through the computer system 10.

The illustrated computer system 10 also includes switch boards 18A and 18B to facilitate the routing circuitry of signals to and from the cell board array 12. The switch boards 18A and 18B generally facilitate the routing circuitry of signals in one or more dimensions, such as along a vertical or horizontal plane, for example. In certain embodiments, the switch boards 18A and 18B communicatively couple to the porous main board 16, directly to the cell board array 12, or to some other component which permits the switch boards 18A and 18B to route signals, for instance. The switch boards 18A and 18B may include several routing circuitry layers through which signals to and from the cell board array 12 may pass. The switch boards 18A and 18B may be passive or active. Active switch boards may include devices such as an ASIC cross-bar chip to route signals actively to and from the various portions of the cell board array 12. Additionally, the switch boards 18A and 18B may communicatively couple to other computer systems, permitting other systems to communicate with the cell board array 12.

In certain embodiments, the computer system 10 may include redundant switch boards 18A and 18B to increase system uptime. In other words, the switch boards 18A and 18B may be adapted to take over the tasks performed by the other switch board in the event that the other switch board ceases to function. Thus, for example, if switch board 18A fails or is removed for repairs, switch board 18B may continue to operate, routing circuitry the signals that switch board 18A would have otherwise carried. Similarly, switch board 18A may support system operations should switch board 18B cease to function. In addition, the switch boards 18A and 18B may be removed, installed, or swapped with other switch boards during system operation or runtime. Thus, the disclosed embodiments may permit certain system repairs or upgrades while the system continues to operate, increasing system uptime and serviceability. In other words, the switch boards 18A and 18B may be redundant, hot-swappable, and hot-pluggable.

The serviceability of the computer system 10 may also be enhanced by the way the switch boards 18A and 18B couple to other components. The switch boards 18A and 18B may couple to the computer system 10 such that the switch boards 18A and 18B may be decoupled and removed from the front or back of the computer system 10. Advantageously, a front-serviceable or rear-serviceable switch board may be serviced without moving the entire computer systems 10 when multiple computer systems 10 are placed side by side. Thus, should a user desire to remove a switch board, the switch boards 18A and 18B may be accessed from the front or back of a computer system 10, without moving the entire computer system 10 out from a row of other computer systems. Moreover, some embodiments provide such serviceability with high system density.

In some embodiments, the switch boards 18A and 18B may couple to the front or rear of the porous main board 16. The switch boards 18A and 18B may couple through connectors that support coupling and decoupling from the front or the rear of the computer system 10. To shorten the path between components, each of the switch boards 18A and 18B may be oriented to lie substantially in a plane that is orthogonal to the cell boards in the cell board array 12. Of course, in other embodiments, the switch boards may be parallel to the cell boards in the cell board array 12.

In another embodiment, one or both of the switch boards 18A and 18B may couple directly to the cell board array 12. In such an arrangement, the switch boards 18A and 18B may couple to the front or back of the cell board array 12 to support front or rear serviceability. Again, the switch boards 18A and 18B may be oriented to lie substantially in a plane orthogonal to the plane of the cell boards to limit the distance a signal may travel between components. Advantageously, front and rear serviceable switch boards 18A and 18B may permit multiple computer systems 10 to be placed side by side without obstructing access to the switch boards 18A and 18B.

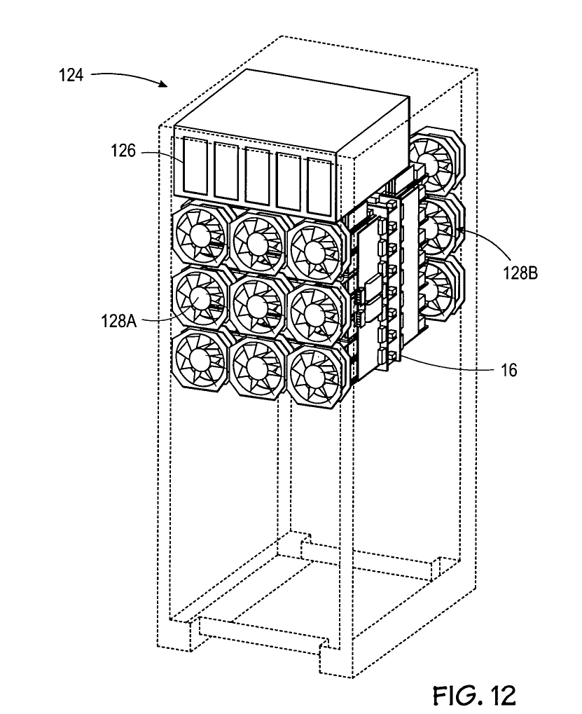

The embodiment of FIG. 1 may also enable airflow in a front-to-back direction or vise versa. The computer system 10 may include fans (such as those depicted by FIG. 12) that blow air through the computer system 10. The circulating air may cool the components within the computer system 10, such as the cell board array 12. Arrows 20 depict exemplary front-to-back airflow through the computer system 10. The airflow 20 is an example of a primary cooling airflow, which may result from a pressure differential employed to cool the computer system 10. The arrows 20 indicate the net displacement of a substantial portion of the air that passes through and carries heat away from the computer system 10. While the cell board array 12 is depicted in FIG. 1 as a solid block for simplicity, certain embodiments of the cell boards within the cell board array 12 are arranged to facilitate air flow between the cell boards. For example, the cell boards may be arranged to lie substantially in a plane that is parallel to the arrows 20. In certain embodiments, the cell boards within the cell board array 12 are arranged to lie substantially in planes that are parallel to arrows 20 and in a horizontal or vertical plane. Thus, airflow 20 may pass through the cell board array 12. Again, the porous main board 16 may include apertures, channels, or other passages through which airflow 20 may pass, thereby improving convective heat transfer and cooling of the system 10. For example, air may pass from the front of the computer system 10, through the cell board array 12, through the porous main board 16, and out the back of the computer system 10.

In addition, the switch boards 18A and 18B may be oriented to facilitate front-to-back airflow 20. For instance, the switch boards 18A and 18B may be oriented to lie substantially in a plane that is parallel to the arrows 20. In some embodiments, the switch boards 18A and 18B may be substantially aligned with the arrows 20, for instance in a horizontal plane, a vertical plane, or some other plane aligned with the arrows 20. In some embodiments, the switch boards 18A and 18B and other switch boards may be in both horizontal and vertical planes. In one embodiment, the switch boards 18A and 18B and the cell boards 12 are all aligned with one another and the arrows 20 in generally parallel and spaced apart horizontal or vertical planes. Advantageously, front-to-back airflow may permit multiple computer systems 10 to be placed side by side without one computer system blowing hot air exhausted by the adjacent system over its internal components.

It should be noted that the embodiment of FIG. 1 may be scalable. For example, through the various connectors on the porous main board 16, switch boards 18A and 18B, and cell board array 12, the computer system 10 may be expanded to include additional components, such as additional cell boards. Additionally, the porous main board 16 may be expanded to interface with multiple cell board arrays 12 and additional switch boards. Moreover, the rear face of the porous main board 16 may couple to additional cell board arrays 12 and switch boards 18A and 18B.

FIG. 2 depicts a perspective view of an exemplary computer system 10 further illustrating an arrangement of four cell board arrays 12A-D coupled to the porous main board 16 in accordance with embodiments of the present technique. The illustrated embodiment of FIG. 2 includes two cell board arrays 12A and 12B coupled to a front face 21 of the porous main board 16 and two cell board arrays 12C and 12D coupled to a rear face 22 of the porous main board 16. Additionally, adjacent each cell board array 12A-D, the computer system 10 of FIG. 2 includes a pair of switch boards 18A-H, collectively referred to as switch boards 18. To illustrate the porous main board 16 more clearly, cell board array 12A includes fewer cell boards than the porous main board 16 supports.

The computer system 10 of FIG. 2 facilitates placement of a number of computer systems 10 side-by-side. The computer system 10 is serviceably from the front or rear of the computer system 10. A service person may remove the switch boards 18 and the cell boards 23 from the front or rear of the computer system 10. As a result, a number of the computer systems 10 may be placed side-by-side without obstructing the removal of the switch boards 18. Additionally, the illustrated embodiment facilitates airflow between the front and rear of the computer system 10.

Each cell board array 12A-D may include a plurality of cell boards 23. The cell boards 23 may include various components that perform computing tasks. For example, the cell boards 23 may include one or more processors and memory. The memory may be in the form of dual inline memory modules (DIMM). Additionally the cell boards may include one or more ASICs, two for example. The ASICs may include controller chips for managing communications between components on the cell boards 23. The cell boards 23 may include power converters to power the operation of these components, such as 48 volt to 1.2 volt power converters. To cool its constituent components, a cell board 23 may include heat sinks coupled to various components, for example the ASICs and processor. The heat sinks may include fins oriented generally parallel to airflow 20 to facilitate the flow of air between the fins.

The cell boards 23 may include various connectors to effectuate communication between the cell boards 23. For instance, cell boards 23 may include connectors 24, 26, and 28 to communicatively couple the cell boards 23 to the porous main board 16. The connectors 24, 26 and 28 may include connectors such as the HMZd connector available from Tyco Electronics of Harrisburg, Pa., or a GBX connector available from Molex of Lisle, Ill., or other similar connector.

In the embodiment of FIG. 2, the porous main board 16 connects to four cell board arrays 12A-D each having up to eight cell boards 23. Thus, the illustrated porous main board 16 supports up to 32 cell boards 23. However, other embodiments may employ a porous main board 16 configured to connect to more or fewer cell board arrays 12 and cell boards 23. To display the porous main board 16 more clearly, cell board array 12A includes five cell boards 23, leaving three empty slots 30 in the porous main board 16. For example, other porous main boards 16 may be configured to couple to one cell board array 12 including up to eight cell boards 23 or two cell board arrays 12 including up to eight cell boards 23 each.

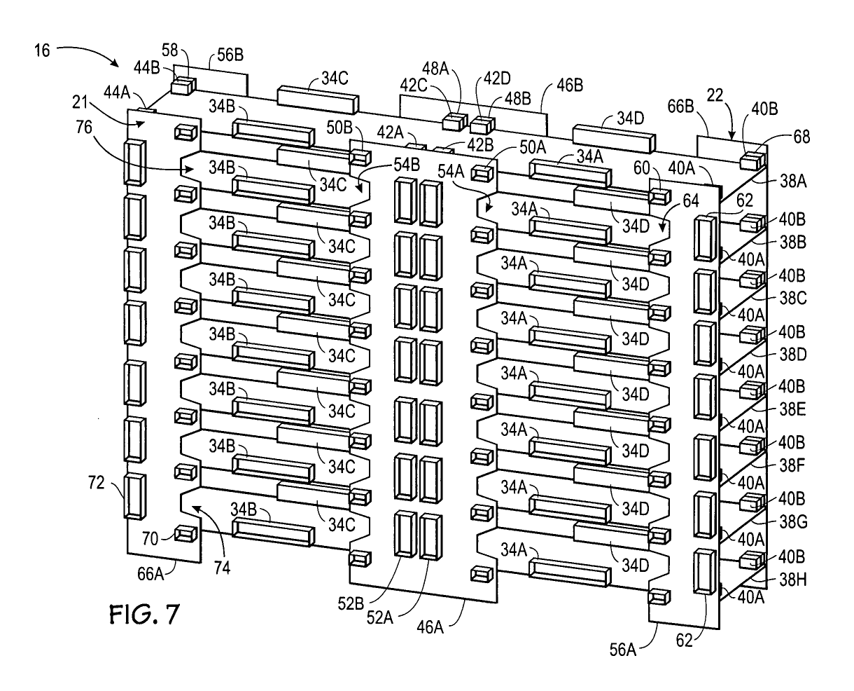

Having introduced the embodiment of FIG.2, the following figures depict various components that may be employed to construct this embodiment. For example, FIGS. 3-6 depict components that may be used to construct a porous main board 16, and FIG. 7 depicts the main board 16 of FIG. 2 without cell boards 23 or switch boards 18 attached. FIG. 8 illustrates an exemplary switch board 18. Finally, FIG. 9 illustrates an alternative exemplary embodiment of a switch board 18.

Turning now to FIG. 3 and with reference to FIGS. 2 and 7, the porous main board 16 may include a horizontal mid-plane 38. The horizontal mid-plane 38 may include several layers of routing circuitry to interconnect the various components to which it connects. The horizontal mid-plane 38 may be active or passive. An active horizontal mid-plane 38 can provide a variety of active components to increase the functionality between the main board 16 and the cell boards 23 and switch boards 18. A passive horizontal mid-plane 38 serves to interconnect the various cell boards 23, switch boards 18, and main board 16 without active components, thereby reducing the likelihood of failure and the need for servicing the horizontal mid-plane 18. Thus, the horizontal mid-plane 18 can remain in place within the porous main board 16, whereas the cell boards 23 and switch boards 18 can be easily removed and serviced from the front or rear of the system 10.

The horizontal mid-plane 38 may communicatively couple to cell boards 23 through connectors 34A-D. Connectors 34A-D may complement connector 26 on the cell boards 23. In the embodiment of FIG. 2, connectors 26 and 34A-D may cooperate to orient cell boards 23 connected to the horizontal mid-plane 38 such that the cell boards 23 lie in a plane substantially parallel to the plane in which the horizontal mid-plane 38 lies. However, other embodiments may employ connectors configured to orient the cell boards at some angle relative to the horizontal mid-plane 38. The horizontal mid-plane 38 may couple to four cell boards 23 through the connectors 34A-D. However, other embodiments may employ more or fewer connectors 34A-D to connect to more or fewer cell boards 23. Additionally, the horizontal mid-plane 38 may include connectors 40A-B, 42A-D, and 44A-B to communicatively couple the horizontal mid-plane 38 to other components of the porous main board 16. Connectors 40A-B, 42A-D, and 44A-B may include connectors such as the HMZd connector available from Tyco Electronics of Harrisburg, Pa., or a GBX connector available from Molex of Lisle, Ill., or other similar connector.

The horizontal mid-plane 38 may employ various routing circuitry layers to connect other components. For example, the horizontal mid-plane 38 may include routing circuitry through which cell boards 23 connected to connectors 34A-D communicate directly or indirectly with one another. In one embodiment, routing circuitry layers may directly communicatively couple each connector 34A-D with every other connector 34A-D. Additionally, the horizontal mid-plane 38 may include routing circuitry layers to communicatively couple connectors 40A-B, 42A-D, and 44A-B to connectors 34. For example, routing circuitry layers may directly communicatively couple connector 34A to connectors 42D and 40B, connector 34B to connectors 44B and 42C, connector 34C to connectors 44A and 42B, and connector 34D to connectors 42A and 40A. It should be noted that these routing circuitry paths are merely exemplary, and other embodiments in accordance with the present technique may employ other routing circuitry paths to connect various components.

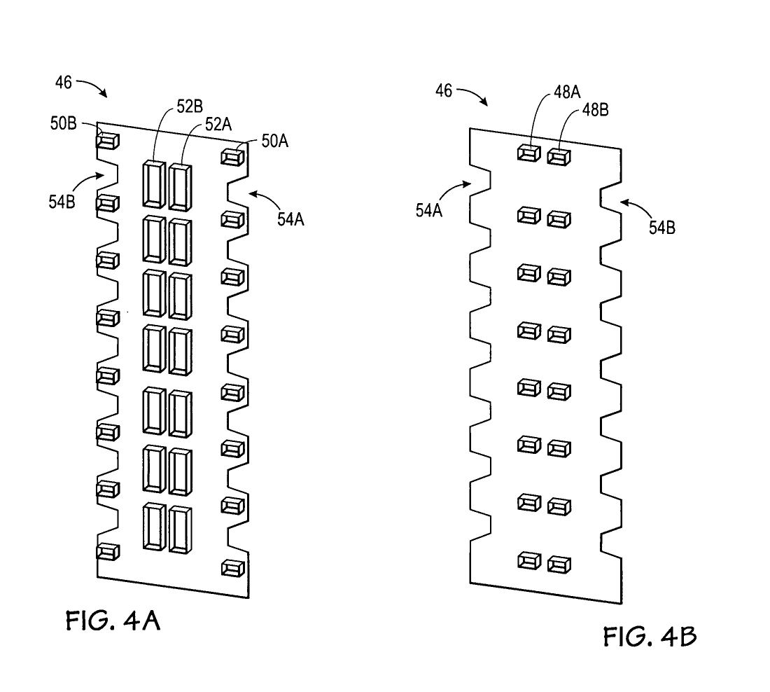

As illustrated by FIGS. 4A and 4B with reference to FIGS. 2 and 7, a center vertical mid-plane 46 is configured to connect to an array of horizontal mid-planes 38. The center vertical mid-plane 46 may vertically position several horizontal mid-planes 38 in spaced relation. For instance, the center vertical mid-plane 46 may be configured to couple to eight parallel horizontal mid-planes 38. To depict the various connectors on the center vertical mid-plane 46, FIG. 4A depicts the front face of an exemplary center vertical mid-plane 46, and FIG. 4B depicts the rear face of an exemplary center vertical mid-plane 46.

As depicted in FIG. 4B, the rear face of the center vertical mid-plane 46 includes two arrays of connectors 48A and 48B. Connectors 48A may complement connectors 42B and 42C on the horizontal mid-plane 38, and connectors 48B may complement connectors 42A and 42D on the horizontal mid-plane 38. Together, connectors 48A and 48B may communicatively couple two center vertical mid-planes 46 to opposing sides of a number of horizontal mid-planes 38. For example, the center vertical mid-plane 46 may include eight pairs of connectors 48A and 48B to couple to eight horizontal mid-planes 38. The connectors 48A and 48B may be arranged in rows to align the horizontal mid-planes 38 in spaced relation, e.g. a spaced vertically parallel configuration. Moreover, the connectors 48A and 48B may be adapted to couple to connectors on both sides of a horizontal mid-plane 38. For instance, two center vertical mid-planes 46 may be employed to support an array of horizontal mid-planes 38 from both sides. In such an embodiment, connectors 48A and 48B of one center vertical mid-plane 46 may connect to connectors 42A and 42B of the horizontal mid-planes 38, and connectors 48A and 48B of another center vertical mid-plane 46 may connect to connectors 42C and 42D of the same horizontal mid-planes 38. Thus, the rear faces of two center vertical mid-planes 46 may symmetrically connect to opposing sides of a number of horizontal mid-planes 38.

As depicted by FIG. 4A with reference to FIGS. 2 and 7, the front face of the center vertical mid-plane 46 includes an array of connectors 50A and 50B to connect directly to cell boards 23. Each pair of the connectors 50A and 50B complements connectors 28 and 24 respectively on cell boards 23, thereby communicatively coupling the center vertical mid-planes 46 directly to two cell boards 23. Thus, while the rear face of the center vertical mid-planes 46 may connect to the horizontal mid-planes 38, the front face of the center vertical mid-planes 46 may connect directly to the cell boards 23. The center vertical mid-plane 46 may include an array of connectors 50A and 50B to connect to an array of cell boards 23, such as a row of eight pairs of cell boards 23. Advantageously, by connecting directly to cell boards 23, the center vertical mid-planes 46 may vertically route signals without adding latency by first passing the signals through the horizontal mid-planes 38 or the switch boards 18.

In addition to connecting to the horizontal mid-planes 38 and the cell boards 23, the center vertical mid-plane 46 may be adapted to communicatively couple to a switch board 18. For example, the illustrated center vertical mid-plane 46 includes an array of connectors 52A and 52B. The array of connectors 52A may connect to one switch board 18, and the row of connectors 52B may connect to a second switch board 18. Thus, in the present embodiment, two switch boards 18 may communicatively couple to the front face of the center vertical mid-plane 46. The connectors 52A and 52B may include connectors such as the the HMZd connector available from Tyco Electronics of Harrisburg, Pa., or a GBX connector available from Molex of Lisle, Ill., or other similar connector.

The center vertical mid-plane 46 may include several routing circuitry layers to communicatively couple the components to which it connects. The routing circuitry layers within the center vertical mid-plane 46 may route signals vertically within the porous main board 16. For instance, the center vertical mid-plane 46 may include routing circuitry to communicatively couple a connector in the array of connectors 50A to an adjacent connector in the array of connectors 52A; a connector in the array of connectors 48A to an adjacent connector in the array of connectors 52A; a connector in the array of connectors 48B to an adjacent connector in the array of connectors 52B; and a connector in the array of connectors 50B to an adjacent connector in the array of connectors 52B. Additionally, the center vertical mid-plane 46 may be passive or active. However, a passive center vertical mid-plane 46 may provide better reliability and serviceability, because a passive center vertical mid-plane 46 may include fewer components thereby reducing the possibility of failure. In short, the center vertical mid-plane 46 may route signals vertically between the cell boards 23, the switch boards 18, and the horizontal mid-planes 38.

The center vertical mid-plane 46 may include apertures, channels, or other passages to enhance airflow 20 through the porous main board 16. For instance, the center vertical mid-plane 46 may include an array of channels 54A on one side and an array of channels 54B on an opposing side. The channels may be arranged to lie between horizontal mid-planes 38 when the center vertical mid-plane 46 is included in a porous main board 16.

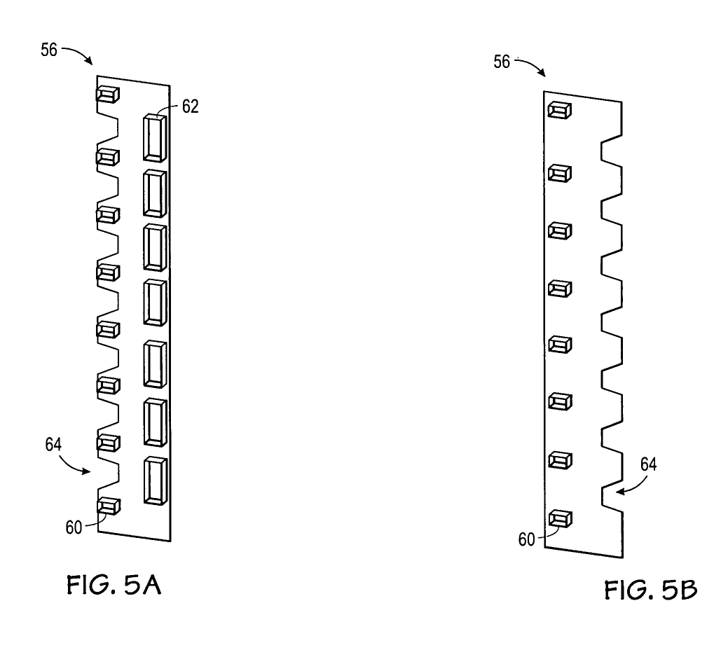

With reference to FIGS. 2 and 7, FIGS. 5A and 5B illustrate front and rear faces of a right vertical mid-plane 56 that cooperates with the center vertical mid-plane 46 to vertically position and interconnect the horizontal mid-planes 38. As illustrated by FIG. 5B, the rear face of an exemplary right vertical mid-plane 56 may include an array of connectors 58, such as eight. Connectors 58 may be similar to the connectors 48A and 48B on the rear face of the center vertical mid-plane 46. The connectors 58 may be adapted to communicatively couple the rear face of the right vertical mid-plane 56 to a horizontal mid-plane 38. Moreover, the connectors 58 may communicatively couple the right vertical mid-plane 56 to an array of horizontal mid-planes, such as eight horizontal mid-planes 38 in spaced relation. For instance, a pair of right vertical mid-planes 56 may couple to opposing sides on opposing ends of an array of eight horizontal mid-planes 38 through connectors 40A or 44B on the horizontal mid-planes 38 with the pair of right vertical mid-planes 56 facing opposing directions.

As illustrated by FIG. 5A, the front face of the right vertical mid-plane 56 may be configured to connect to cell boards 23 and switch boards 18. For instance, the right vertical mid-plane 56 may include an array of connectors 60 that may be similar to connectors 50A and 50B on the front face of the center vertical mid-plane 46. Connectors 60 may directly communicatively couple the right vertical mid-plane 56 directly to cell boards 23. To this end, connectors 60 may complement connectors 28 on the cell boards 23. A right vertical mid-plane 56 may be configured to connect directly to a series of cell boards 23, such as eight. Additionally, the front face of a right vertical mid-plane 56 may include an array of connectors 62 to communicatively couple the right vertical mid-plane 56 to a switch board 18. Complementing these connectors, the right vertical mid-plane 56 may include several routing circuitry layers to place the various components to which it connects in communication.

The right vertical mid-plane 56 may include features to enhance airflow through the porous main board 16. For example, the right vertical mid-plane 56 may include channels 64 to increase the size of apertures that are formed when the right vertical mid-plane 56 is employed to construct a porous main board 16. The illustrated right vertical mid-plane 56 includes an array of seven channels 64. When assembled into a porous main board 16, each channel 64 may lie between the horizontal mid-planes 38 that may be coupled to the right vertical mid-plane 56.

With reference to FIGS. 2 and 7, FIGS. 6A and 6B illustrate front and rear faces of an exemplary left vertical mid-plane 66. The left vertical mid-plane 66 may be symmetric to the right vertical mid-plane 56. For instance, an array of connectors 68 may communicatively couple the rear face of a pair of left vertical mid-planes to opposing sides and opposing ends of an array of horizontal mid-planes 38. To this end, connectors in the array of connectors 68 may complement connectors 44A and connectors 40B on a horizontal mid-plane 38. Similarly, an array of connectors 70 may couple the front face of a left vertical mid plane to cell boards 23 through connector 24 on the cell boards. Also on the front face, an array of connectors 72 may connect the left vertical mid-plane to a switch board 18. Additionally, the left vertical mid-plane may include apertures or channels 74 to enhance airflow 20 through the porous main board 16.

An exemplary porous main board 16 may be formed from horizontal mid-planes 38, center vertical mid-planes 46, right vertical mid-planes 56, and left vertical mid-planes 66. FIG. 7 illustrates an embodiment of the porous main board 16 that may be formed from these components. The illustrated porous main board 16 includes an array of eight horizontal mid-planes 38A-H configured to horizontally route signals to and from the cell boards 23. A pair of center vertical mid-planes 46A and 46B couples the horizontal mid-planes 38A-H to route signals vertically among the cell boards 23 and switch boards 18. Additionally, a pair of right vertical mid-planes 56A and 56B and a pair of left vertical mid-planes 66A and 66B are coupled to opposite sides and opposite ends of the horizontal mid-planes 38A-H, thereby facilitating the routing of signals vertically among the cell boards 23 and switch boards 18.

Advantageously, the porous main board 16 of the present embodiment facilitates air flow through the computer system 10, thereby facilitating high system density. As illustrated in FIG. 7, the porous main board 16 includes a matrix of apertures 76 though which air may flow. These apertures 76 may be placed such that air may flow from the front of the porous main board 16 to the rear of the porous main board 16. The apertures 76 may be bounded by a pair of adjacent horizontal mid-planes 38, the center vertical mid-planes 46A and 46B, a right vertical mid-plane 56A or 56B, and a left vertical mid-plane 66B or 66A. Thus, the present embodiment may include seven apertures 76 per pair of cell board arrays 12, or 14 apertures 76. However, other embodiments may include more or fewer apertures 76.

Additionally, the porous main board 16 of the present embodiment may be configured to receive one or more (e.g., multiple redundant) hot-pluggable, hot-swappable switch boards 18 that are accessible from the front or back of a cabinet. Referring to the embodiments of FIGS. 2 and 7, the center vertical mid-plane 46A may couple to a pair of switch boards 18B and 18C through connectors 52A and 52B, the right vertical mid-plane 56A may connect to a switch board 18A through connector 62, and the left vertical mid-plane 66A may couple to a switch board 18D through connector 72. Similarly, the rear face of the porous main board 16 may connect to switch boards 18E-H with reference to FIGS. 2 and 7. Thus, the porous main board 16 may be configured to couple to four switch boards 18A-D on its front face and four switch boards 18E-H on its rear face, or two switch boards 18 per cell board array 12. Of course, the porous main board 16 could be configured to connect to any number of switch boards in other embodiments. Advantageously, in some embodiments, one switch board 18 may be removed while the computer system 10 continues to operate, increasing system uptime. Additionally, when the switch board 18 is coupled to the porous main board 16, the system 10 may consume very little space for air management, thereby increasing system density. Moreover, the switch boards 18 may be decoupled from the front or back of the system, increasing system serviceability.

FIG. 8 depicts an exemplary switch board 18 that may couple to the porous main board 16. The switch board 18 may cooperate with the center vertical mid-plane 46, right vertical mid-plane 56, and left vertical mid-plane 66 to vertically route signals. The switch board 18 may be passive or active. For instance, switch board 18 may include logic circuits 78A and 78B to actively route signals. Logic circuits 78A and 78B may be ASICs, or “cross-bar” chips, communicatively coupled to the switch board 18. A cross-bar chip can access a number of input and output data lines and internally reconfigure which input lines are connected to which output lines. The logic circuits 78A and 78B may arbitrate the routing of information between devices connected to the switch board 18, for instance the cell boards 23. While two logic circuits 78A and 78B may be employed by the present embodiment, other embodiments in accordance with the present techniques may employ more or fewer logic circuits or no logic circuits. In some embodiments, heat sinks may be affixed to the logic circuits 78A and 78B to dissipate heat. Additionally, the switch board 18 may include cabinet-to-cabinet fabric connectors 80A and 80B. These connectors 80A and 80B may permit multiple cabinets to be connected. In some embodiments, connectors 80A and 80B may be used for I/O connections. Connectors 80A and 80B may be implemented as copper wires or as optical cables, for example. The switch board 18 may also include an array of connectors 82 to couple the switch board 18 to the porous main board 16. Thus, connectors 82 may complement connectors 52A and 52B on the center vertical mid-plane 46, connectors 62 on the right vertical mid-plane 56, and connectors 72 on the left vertical mid-plane 66. The array of connectors 82 may include connectors such as the HMZd connector available from Tyco Electronics of Harrisburg, Pa., or a GBX connector available from Molex of Lisle, Ill., or other similar connector.

The switch board 18 may include routing circuitry layers that communicatively couple its various connectors to the logic circuits 78A and 78B. For example, the switch board 18 may include routing circuitry layers that connect each connector 82 to each logic circuit 78A and 78B. These routing circuitry layers may permit cell boards 23 that are connected to different horizontal mid-planes 38 to communicate with one another. In some embodiments, the switch boards 18 span between a pair of stacked porous mid-planes 16 and route signals between the two. It should also be noted that the switch boards 18 may span a portion of a porous mid-plane 16, for example in a system with adjacent switch boards 18 that are vertically stacked in the same plane on a porous mid-plane 16. In other words, a number of shorter switch boards may be placed end to end.

FIG. 9 depicts an alternate embodiment of a switch board 84. The switch board 84 may include additional logic circuits to mitigate larger signal latency and attenuation resulting from longer distances between devices. The switch board 18 may include four logic circuits 86A-D to shorten the distance between components, boosting signal strength due to proximity. The logic circuits 86A-D may include cross-bar chips to actively route signals. Heat sinks may couple to the logic circuits 86A-D to dissipate heat. The switch board 84 may include connectors 82 to connect to the porous main board 16. Four fabric connectors 88A-D may communicate with the logic circuits 86A-D to facilitate cabinet to cabinet connections or other input or output connections.

The switch board 84 may include routing circuitry layers to communicatively couple the other devices. For instance, the routing circuitry layers may connect logic circuits 86A -86D to each of the connectors 82. Additionally, the routing circuitry layers may communicatively couple the logic circuits 86A-D to one another. For instance, routing circuitry layers may connect logic circuit 86B to logic circuit 86D. Routing circuitry layers within the switch board 84 may also connect the fabric connectors 88A-D to one or more of the logic circuits 86A-D, for instance fabric connector 88C may connect to logic circuit 86C.

Referring back to FIG. 2, it is important to note that the present embodiment may be modular and scalable. For example, fewer cell boards 23 may be coupled to the porous main board 16. Moreover, the porous main board 16 may have the capacity to couple to fewer or more cell boards 23. For example, the porous main board 16 may be adapted to couple to one or two of the cell board arrays 12 by employing half sized horizontal mid-planes 38 and eliminating the center vertical mid-plane 46. Such an embodiment may couple to two cell board arrays 12, one on its front face and one on its rear face, and four switch boards 18. Additionally, the embodiment of FIG. 2 may be scaled up to a larger system. For example, the size of the cell board arrays 12 may be increased by including a larger porous main board 16, for example with more horizontal mid-planes 38. In another example of a larger embodiment, a computer system 10 may include longer horizontal mid-planes 38 with more connectors to support additional cell board arrays 12.

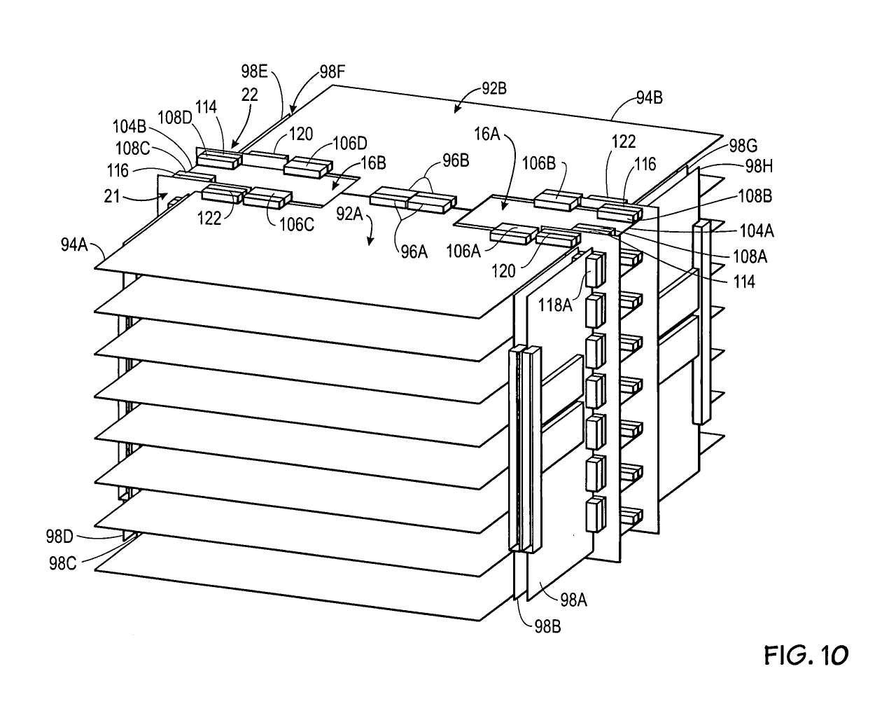

Other embodiments in accordance with the present technique may employ cell board arrays 12 that couple directly to one another. For example, FIG. 10 depicts a computer system 90 with a pair of cell board arrays 92A and 92B. Each cell board array 92A and 92B may include a number of cell boards 94A and 94B (collectively referred to as cell boards 94), such as eight for instance. The cell boards 94 within the cell board arrays 92A and 92B may be in spaced relation, for example parallel and in a vertical column. The cell boards 94A and 94B may be adapted to couple communicatively directly to one another. For example, cell board 94A may couple directly to cell board 94B. Similarly, other horizontally adjacent cell boards 94A and 94B within the cell board arrays 92A and 92B may couple directly to one another. The cell boards 94A and 94B may include connectors 96A and 96B respectively to place the cell boards 94A and 94B in direct communication. Connectors 96A and 96B may be complementary connectors configured to couple cell boards 94A and 94B communicatively to one another. For example, the connectors 96A and 96B may include the HMZd connector available from Tyco Electronics of Harrisburg, Pa., or a GBX connector available from Molex of Lisle, Ill., or other similar connector. Advantageously, direct cell board 94A to cell board 94B connections tend to reduce latency in some embodiments.

Each cell board 94 may include components to perform computing functions. For example, each cell board 94 may include a number of processors, such as two for example. The processors may connect to a number of memory modules and to one another. Additionally, cell boards 94 may include a number of ASICs, such as four, to route signals between the processors on the cell board 94 and to route signals to and from the cell board 94. Advantageously, such an arrangement may enhance the computing speed of the system. Several processors may be directly connected to one another. For example, the processors on the same cell board 94 may be able to communicate at high bandwidths due to their proximity. Similarly, the processors on the cell boards 94 that are connected directly to one another may also employ high bandwidth communication with one another. It should also be noted that heat sinks may be coupled to various components on the cell boards 94 to dissipate heat from the components, such as the ASICs and the processors or any other high power device.

The embodiment of FIG. 10 may include switch boards 98A-H (collectively referred to as switch boards 98) to vertically route signals to and from the cell boards 94. The computer system 10 may employ a number of switch boards 98, such as eight. However, other systems in accordance with the present technique may employ more or fewer switch boards 98. For instance, the number of switch boards 98 may be double the product of the number of cell board arrays 92 and the number of processors on a cell board 94. The switch boards 98 may couple to the computer system 90 through an array of connectors 100 that may be similar to connectors 82 employed by the switch board of FIG. 8. Additionally, the switch boards 98 may include logic circuits 102A-D to route signals actively to and from the cell boards 94. The logic circuits 102A-D may include cross bar chips with attached heat sinks. The switch boards 98 may also include routing circuitry layers to couple the logic circuits 102A-D communicatively to the various connectors on the switch boards 98. For example, the switch boards 98 may include routing circuitry to connect each logic circuit 102A-D to each connector in the array of connectors 100.

Advantageously, the switch boards 98 of the present embodiment may be front or rear serviceable, hot-pluggable, and hot-swappable. The switch boards 98 may couple to the computer system 90 such that they may be decoupled and removed from the front or rear of the computer system 90. Additionally, the number of switch boards 98 in the computer system 90 may be selected for redundancy such that if one switch board 98 is removed, the computer system 90 may continue to operate.

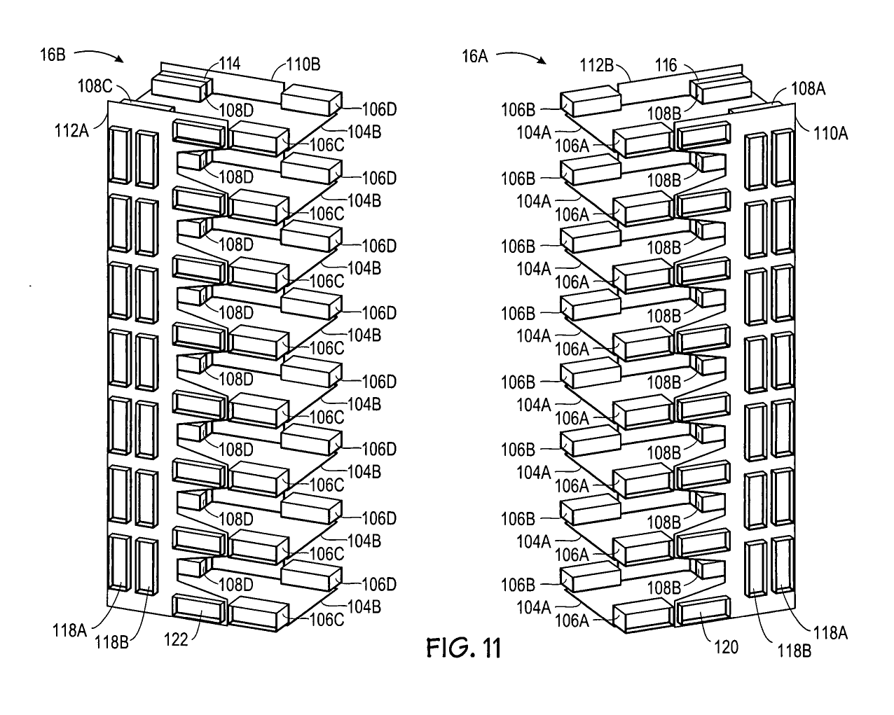

The embodiment of FIG. 10 may employ a split porous main board 16A and 16B to leave room for the cell board arrays 92A and 92B to couple directly to one another. FIG. 11 depicts an exemplary split porous main board 16A and 16B. However, it should be noted that other embodiments in accordance with the present technique may employ one split porous main board 16A or 16B. Each cell board 94 in cell board arrays 92A and 92B may connect to one of an array of pairs of horizontal mid-planes 104A and 104B. The horizontal mid-planes 104A may include connectors 106A and 106B to couple the horizontal mid-planes 104A communicatively to connectors on the cell boards 94. Similarly, the horizontal mid-planes 104B may include connectors 106C and 106D to mate with connectors on the cell boards 94. Thus, each horizontal mid-plane 104A and 104B may directly connect to a cell board in cell board arrays 92A and 92B. Moreover, the horizontal mid-plane 104A and horizontal mid-plane 104B may include connectors to connect to components adapted to route signals vertically. For instance, connectors 108A and 108B on horizontal mid-planes 104A and connectors 108C and 108D on horizontal mid-plane 104B may connect to components configured to route signals vertically. Each horizontal mid-plane 104A and 104B may include routing circuitry layers to route signals horizontally. For example, routing circuitry layers in horizontal mid-planes 104A may communicatively couple connectors 106A to connectors 108B and connectors 106B to connectors 108A. Similarly, routing circuitry layers in horizontal mid-planes 104B may communicatively couple connectors 106C to connectors 108D and connectors 106D to connectors 108C.

The porous main board 16A and 16B of FIG. 11 may include a pair of right vertical mid-planes 110A and 110B (collectively referred to as right vertical mid-planes 110) and a pair of left vertical mid-plane 112A and 112B (collectively referred to as left vertical mid-planes 112) to route signals vertically and support the cell board arrays 92A and 92B. The pair of right vertical mid-planes 110A and 110B may each communicatively couple to an array of horizontal mid-planes 104A and 104B respectively. The right vertical mid-planes 110 may couple to the horizontal mid-planes 104A and 104B through an array of connectors 114 configured to couple to connectors 108A or 108D on the array of horizontal mid-planes 104A or 104B. Similarly, the left vertical mid-planes 112A and 112B may connect to a pair of arrays of horizontal mid-planes 104B and 104A respectively. The left vertical mid-planes 104 may connect through an array of connectors 116 that are adapted to couple communicatively to connectors 108B or 108C. Additionally, the right and left vertical mid-planes 110 and 112 may each include an array of connectors 120 or 122 to connect directly to cell board arrays 92A and 92B.

The right and left vertical mid-planes 110 and 112 may include an array of connectors 118A and 118B to each connect to a pair of switch boards 98. The connectors 118A and 118B may be adapted to couple communicatively to the array of connectors 100 on the switch boards 98. Additionally, the right and left vertical mid-planes 110 and 112 may include routing circuitry layers through which signals may pass between the various connectors. For example, each connector in the array of connectors 114 or 116 may connect to an adjacent connector in the array of connectors 118A and 118B. Similarly, each connector in the array of connectors 120 or 122 may connect to an adjacent connector in the array of connectors 118A and 118B. Thus, a pair of right vertical mid-planes 110 may cooperate with a pair of left vertical mid-planes 112 to couple the porous main boards 16A and 16B together.

FIG. 12 illustrates a computer system 10 including a rack, enclosure, or cabinet 124. The cabinet 124 may include a bulk power unit 126 to power the operation of the cell boards 23. The bulk power unit 126 may connect to the cell boards 23 through the porous main board 16, or it may connect directly to the cell boards 23. A matrix of intake fans 128A may blow air into the front of the cabinet 124, and a matrix of exhaust fans 128B may blow air out of the cabinet 124. Together, fans 128A and 128B may circulate air over the cell boards 23, cooling their components. Advantageously, the fans 128A and 128B may blow air directly through the porous main board 16, permitting front-to-back airflow with or without a plenum or venting along the sides. With front-to-back airflow, a series of closely placed cabinets 124 may operate at lower temperatures. For instance, a series of cabinets 124 may be placed in a row without the exhaust fans 128B of one cabinet being directed toward the intake fans 128A of another cabinet. Additionally, in some embodiments, the intake fans 128A continue to circulate air when the rear fans 128B are disabled during a service operation (and vice versa), thereby facilitating increased system up-time. The cabinet 124 may house a variety of arrangements of cell board arrays 12, such as the embodiment of FIG. 2, an embodiment with the switch board of FIG. 9 coupled to the embodiment of FIG. 2, or the embodiment of FIG. 10, for example.

Other embodiments in accordance with the present technique may form a porous structure that may or may not include a porous mid-plane 16. For example, other embodiments may include an array of horizontal mid-planes 38 spaced apart by switch boards 18. That is, the switch boards 18 may be orthogonally oriented edge-to-edge with the horizontal mid-planes 28 to form a porous structure. Some of these embodiments may omit the center, right, and/or left vertical mid-planes 46, 56, and/or 66, which is not to suggest that any other features may not also be omitted.

While the invention may be susceptible to various modifications and alternative forms, specific embodiments have been shown by way of example in the drawings and will be described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A computer system, comprising:
a porous circuit board having a front and a back, wherein the porous circuit board comprises a plurality of air passages extending between the front and the back;
a cell board connector coupled to the porous circuit board; and
a switch board connector coupled to the porous circuit board, wherein the switch board connector is configured to couple a switch board removably to the porous circuit board in a frontward or backward direction relative to the front or the back respectively.

2. The computer system of claim 1, wherein the porous circuit board comprises a plurality of circuit boards coupled together in a spaced relationship, wherein the plurality of air passages include spaces between the plurality of circuit boards.

3. The computer system of claim 2, wherein the plurality of circuit boards comprise a front porous circuit board disposed at the front and a back porous circuit board disposed at the back.

4. The computer system of claim 3, wherein the plurality of circuit boards comprise intermediate boards between the front porous circuit board and the back porous circuit board.

5. The computer system of claim 4, wherein the front and back porous circuit boards each comprise a left vertical mid-plane and a right vertical mid-plane, and the intermediate boards comprise a plurality of horizontal mid-planes coupled to each of the left vertical mid-planes and to each of the right vertical mid-planes.

6. The computer system of claim 5, wherein the front and back porous circuit boards each comprise a center vertical mid-plane coupled to the plurality of horizontal mid-planes.

7. The computer system of claim 6, comprising:
a plurality of cell boards, wherein each cell board is coupled to at least one of the plurality of horizontal mid-planes and at least one of the center vertical-mid planes; and
a plurality of switch boards, wherein each switch board is coupled to the left vertical mid-plane, or the right vertical mid-plane, or the center vertical mid-plane, or a combination thereof.

8. The computer system of claim 1, comprising a plurality of cell board connectors including the cell board connector, where the plurality of cell board connectors each have a release direction that is substantially orthogonal to the front or back.

9. The computer system of claim 1, comprising the switchboard removably coupled to the switch board connector, wherein the switch board is hot-swappable.

10. The computer system of claim 9, wherein the switch board is substantially orthogonal to the front or the back.

11. The computer system of claim 1, comprising a cell board and the switch board removably coupled to the porous circuit board in a spaced relationship, wherein the plurality of air passages are aligned with space between the cell board and switch board.

12. The computer system of claim 1, comprising a plurality of cell boards and a plurality of switch boards removably coupled to the front, or the back, or a combination thereof, wherein the plurality of cell boards and the plurality of switch boards are disposed in a spaced relationship

13. The computer system of claim 1, wherein:
the cell board connector is coupled to the front of the porous circuit board or the back of the porous circuit board; and
the switch board connector is coupled to the front of the porous circuit board or the back of the porous circuit board.

14. The computer system of claim 1, comprising a cell board coupled to the cell board connector, wherein the cell board is substantially parallel to a primary cooling airflow in the frontward or backward direction through the computer system.

15. A method of operating a computer system, comprising:
enabling airflow through a porous structure; and
removably supporting a switch board in a frontward or backward direction relative to the porous structure.

16. The method of claim 15, wherein the airflow is in a frontward or backward direction.

17. The method of claim 15, wherein the porous structure comprises a porous circuit board.

18. A method of manufacturing a computer system, comprising providing a porous main board having a plurality of connectors disposed on a front, or a back, or the front and back of the porous main board, wherein the plurality of connectors are configured to couple to a plurality of switch boards that are removable from the porous main board from the front, or the back, or the front and back.

19. The method of claim 18, comprising providing a plurality of boards including the plurality of switch boards, wherein the plurality of boards are hot-pluggable with the porous main board.

20. The method of claim 18, wherein the step of providing a porous main board comprises providing a plurality of spaced apart circuit boards.
